(19) United States
(12) Patent Application Publication
(10) Pub. No.: US 2014/0092566 A1
(43) Pub. Date: Apr. 3, 2014

(54) ELECTRONIC DEVICE

(71) Applicant: KABUSHIKI KAISHA TOSHIBA, TOKYO (JP)

(72) Inventors: Hideo SHIRASAKA, Tokyo (JP); Yuji NAKAJIMA, Tokyo (JP)

(21) Appl. No.: 13/905,981

(22) Filed: May 30, 2013

(30) Foreign Application Priority Data
Sep. 28, 2012 (JP) 2012-216579

(51) Int. Cl. H05K 5/00

(52) U.S. Cl. CPC H05K 5/0017
USPC 361/749

(57) ABSTRACT

According to one embodiment, device includes first housing, second housing, flexible display, and driving portion. The first housing includes first surface. The second housing is foldably connected to the first housing and includes second surface positioned close to the first surface in folded state and positioned away from the first surface in unfolded state. The display is stored in storage provided to the first housing, at least partially covers the second surface in state in which at least portion of the display is out of the storage, and is supported by the first housing and the second housing. The driving portion moves the display in direction toward which the display is ejected from the storage by motion of the driving portion associated with unfolding, and moves the display in direction toward which the display is retracted into the storage by the motion of the driving portion associated with folding.

### CROSS-REFERENCE TO RELATED APPLICATIONS

This application is based upon and claims the benefit of priority from Japanese Patent Application No. 2012-216579, filed Sep. 28, 2012; the entire contents of which are incorporated herein by reference.

### FIELD

An embodiment described herein relates generally to an electronic device.

### BACKGROUND

Conventionally, there has been known a deformable electronic device having a flexible display.

In such electronic device, it is desirable to obtain a structure that is more usable by leveraging flexibility of the flexible display.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of an electronic device in an unfolded state according to an embodiment;

FIG. 2 is an exemplary perspective view of an internal structure of a first housing of the electronic device in the unfolded state, in the embodiment;

FIG. 3 is an exemplary plan view of the internal structure of the first housing of the electronic device in the unfolded state, in the embodiment;

FIG. 4 is an exemplary perspective view of the internal structure including a driving portion of the electronic device, in the embodiment;

FIG. 5 is an exemplary side view (partially cross-sectional view) of the internal structure including the driving portion of the electronic device, in the embodiment;

FIG. 6 is an exemplary side view of a rotating portion comprised in the driving portion of the electronic device, in the embodiment;

FIG. 7 is an exemplary cross-sectional view of a portion of the electronic device in the folded state, in the embodiment;

FIG. 8 is an exemplary cross-sectional view of a portion of the electronic device in the unfolded state, in the embodiment;

FIG. 9 is an exemplary perspective view of a movable portion provided to a second housing of the electronic device in a state in which the movable portion is shrunk, in the embodiment;

FIG. 10 is an exemplary perspective view of the movable portion provided on the second housing of the electronic device in a state in which the movable portion is stretched, in the embodiment;

FIG. 11 is an exemplary plan view of a portion of an electronic device and illustrating a state in which a flexible display is stored, according to a first modification;

FIG. 12 is an exemplary plan view of the portion of the electronic device and illustrating a state in which the flexible display is protruded, in the first modification;

FIG. 13 is an exemplary perspective view of an internal structure comprising a driving portion of an electronic device according to a second modification;

FIG. 14 is an exemplary side view of a rotating portion comprised in a driving portion of an electronic device according to a third modification;

FIG. 15 is an exemplary perspective view of a movable portion provided to a second housing of an electronic device in a state in which the movable portion is shrunk, according to a fourth modification;

FIG. 16 is an exemplary perspective view of the movable portion provided to the second housing of the electronic device in a state in which the movable portion is stretched, in the fourth modification;

FIG. 17 is an exemplary cross-sectional view of a guide provided to a first housing of an electronic device according to a fifth modification;

FIG. 18 is an exemplary cross-sectional view of a portion of an electronic device in a folded state according to a sixth modification;

FIG. 19 is an exemplary cross-sectional view of a portion of the electronic device in an unfolded state in the sixth modification;

FIG. 20 is an exemplary cross-sectional view of a portion of the electronic device in the unfolded state and illustrating a state in which the electronic device is unfolded for an amount wider than that in FIG. 19 in the sixth modification;

FIG. 21 is an exemplary front view (partially cross-sectional view) of a driving portion of an electronic device according to a seventh modification;

FIG. 22 is an exemplary perspective view of the driving portion of the electronic device in the seventh modification;

FIG. 23 is an exemplary cross-sectional view of a portion of an electronic device in a folded state according to an eighth modification;

FIG. 24 is an exemplary side view (partially cross-sectional view) of an internal structure comprising a driving portion of an electronic device according to a ninth modification;

FIG. 25 is an exemplary plan view of a portion of a movable portion of the electronic device, in the ninth modification;

FIG. 26 is an exemplary plan view of an internal structure of a first housing of the electronic device in the unfolded state in the ninth modification;

FIG. 27 is an exemplary side view of a structure comprising a driving portion of an electronic device according to a tenth modification; and

FIG. 28 is an exemplary side view of the structure comprising the driving portion of the electronic device in a state in which the electronic device is unfolded for an amount wider than that in FIG. 27 in the tenth modification.

### DETAILED DESCRIPTION

In general, according to one embodiment, an electronic device comprises a first housing, a second housing, a flexible display, and a driving portion. The first housing comprises a first surface to which a keyboard is provided. The second housing is configured to be foldably connected to the first housing and comprises a second surface positioned close to the first surface in a folded state and positioned away from the first surface in an unfolded state. The flexible display comprises a display surface on which an image is displayed, is configured to be stored in a storage provided to the first housing in an ejectable-retractable manner, is configured to at least partially cover the second surface in a state in which at least a portion of the flexible display is out of the storage, and is configured to be supported by the first housing and the second housing. The driving portion is configured to move the flexible display in a direction toward which the flexible display is ejected from the storage by motion of the driving portion associated with unfolding of the first casing and the second casing, and is configured to move the flexible display in a direction toward which the flexible display is retracted into the storage by the motion of the driving portion associated with folding of the first housing and the second housing.

An exemplary embodiment and modifications in the following comprise the same or similar constituent elements. In the following description, the same or similar constituent elements are given with common reference numerals or signs, and redundant explanations are omitted.

While the following embodiment and modifications describe examples in which an electronic device is configured as a personal computer, the electronic device according to the embodiment is not limited thereby. The electronic device in the embodiment can be configured as a television receiver, a cellular phone, a smartphone, a personal digital assistant (PDA), an office machine, an electronic dictionary, a game machine, a video display device, a video reproducing device, and such.

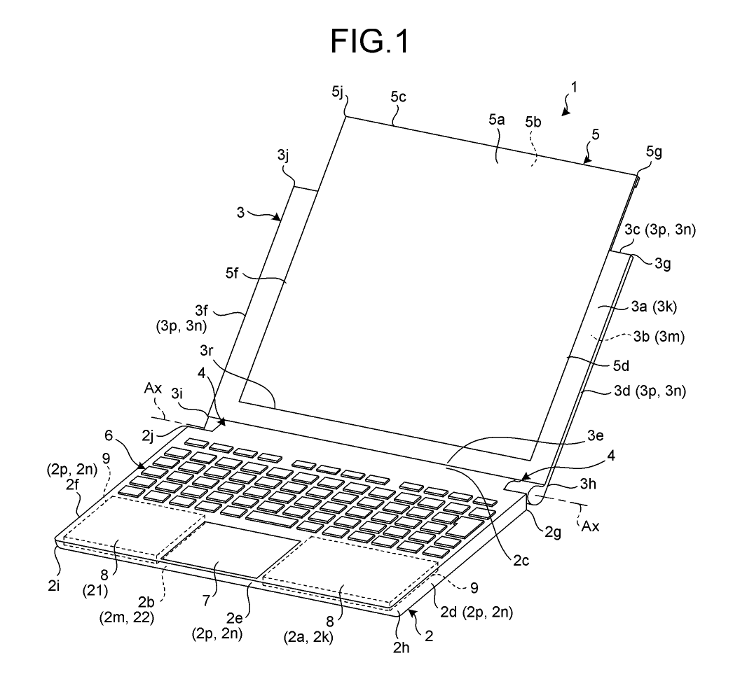

In the embodiment, as illustrated in FIG. 1 as one example, an electronic device 1 comprises a housing 2 (first housing or first portion) and a housing 3 (second housing or second portion). The housing 2 and the housing 3 support a display 5. The housing 2 is configured in a rectangular parallelepiped shape to be thin and flat in the thickness direction thereof. The housing 2 appears in a quadrangular shape (in the embodiment, a rectangular shape as one example) as viewed from the thickness direction (planar view). The housing 3 is configured in a rectangular parallelepiped shape to be thin and flat in the thickness direction thereof. An end portion 2c of the housing 2 and an end portion 3e of the housing 3 are connected to be rotatable (foldable) about a rotational axis Ax via a hinge 4. The size of the housing 2 as viewed from the thickness direction (planar view) and that of the housing 3 as viewed from the thickness direction are nearly the same. The housing 3 can be rotated (moved) between a given position at which the housing 3 is positioned away from the housing 2 thereby unfolded (in the embodiment, the given position corresponds to a state in which an angle of nearly 180 degrees is formed between the housing 2 and the housing 3, a state in which the housing 3 is aligned with the housing 2 in a planar manner, a flat state, a spaced-apart state, an unfolded state, a second state, or a second posture as one example) and a position at which the housing 3 is placed close to the end portion 2c thereby folded (in the embodiment, the position corresponds to a state in which an angle of nearly zero degrees is formed between the housing 2 and the housing 3, a state in which the housing 2 overlaps the housing 3 in the thickness direction, a state in which the housing 3 is along with the housing 2, a folded state, a closely situated state, a first state, or a first posture as one example). The electronic device 1 is further provided with a resistive element (for example, a disc spring, not illustrated) that causes resistive torque (rotational resistance) between the housing 2 and the housing 3. The resistive element maintains an angle formed between the housing 2 and the housing 3. When an operator exerts a rotational torque exceeding the resistive torque between the housing 2 and the housing 3, the housing 2 and the housing 3 can be rotated (positions are changed). The magnitude of resistive torque is set such that the housing 2 and the housing 3 do not rotate by their own weight, vibration, and such.

The housing 2 in the embodiment comprises a surface 2a (anterior surface, top surface, front face, or surface portion) and a surface 2b (rear surface, bottom surface, back surface, or surface portion) opposite the surface 2a as one example. Both the surface 2a and the surface 2b extend (expand) along a direction intersecting the thickness direction of the housing 2 (in the embodiment, in an orthogonal direction as one example). The surface 2a and the surface 2b are roughly in parallel with each other. As illustrated in FIGS. 1 to 3, the housing 2 further comprises four end portions 2c to 2f (sides or edge portions) and four corners 2g to 2j (protruding portions, rounded portions, or end portions) in the planar view. The end portions 2c and 2e are examples of longer sides. The end portions 2d and 2f are examples of shorter sides.

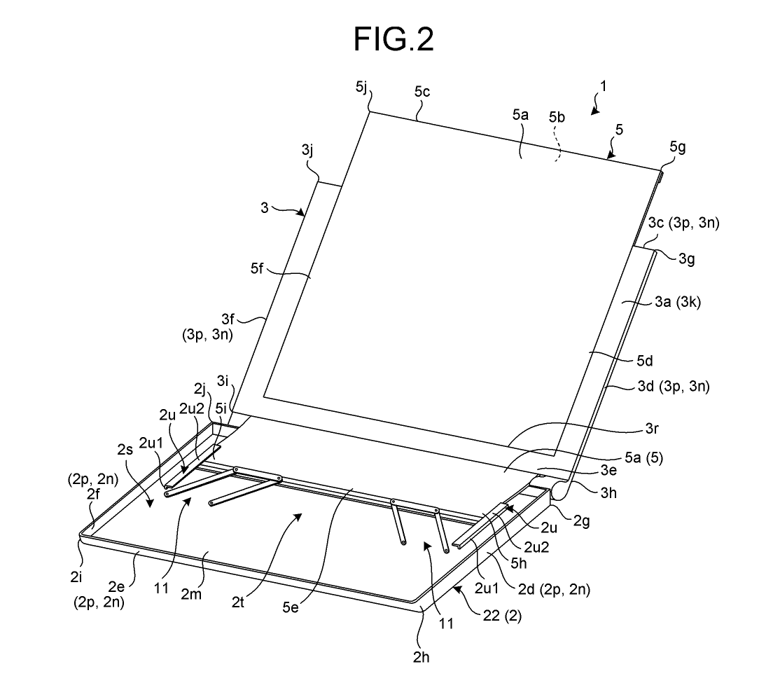

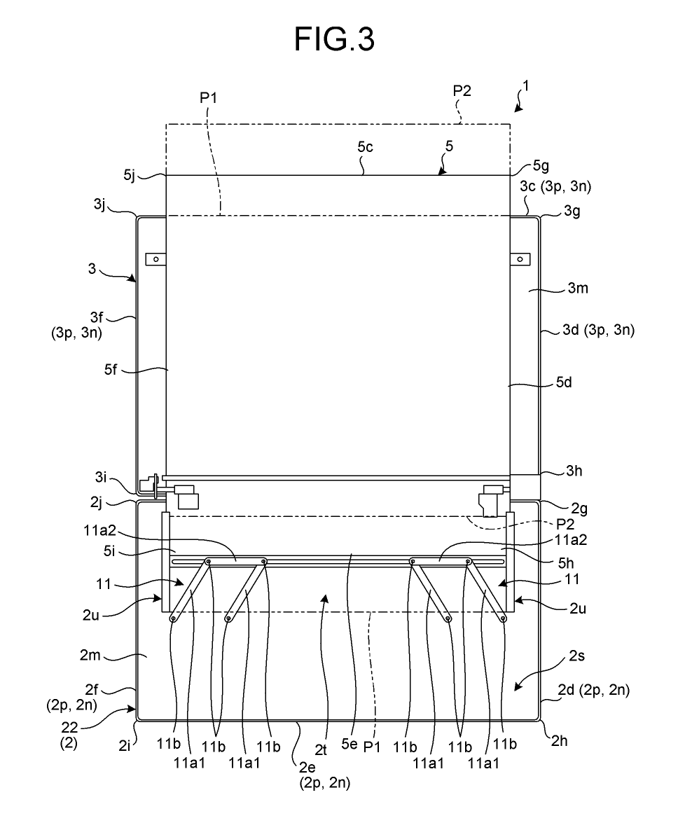

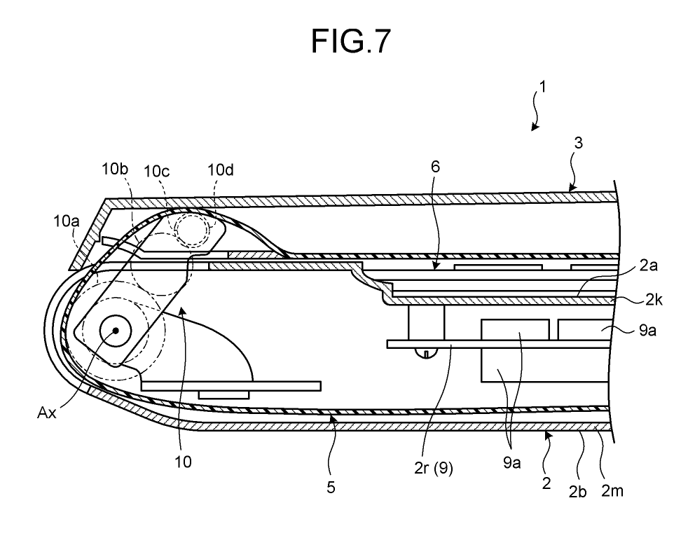

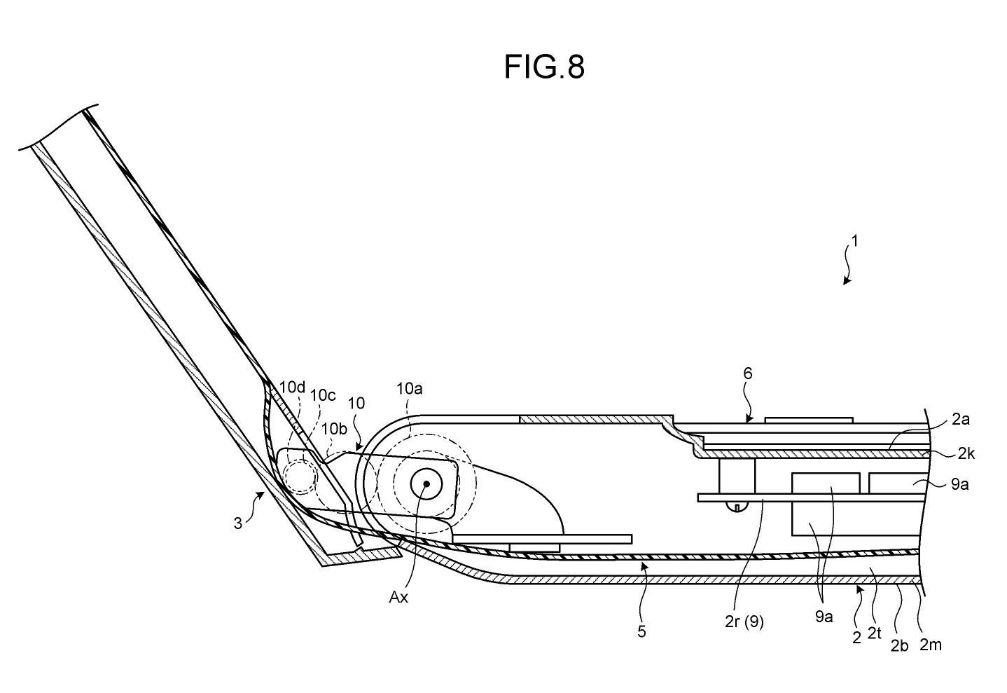

Furthermore, the housing 2 comprises a wall 2k (part, plate, frame, front wall, surface wall, or top wall) having the surface 2a (first surface), and a wall 2m (part, plate, rear wall, back wall, or bottom wall) having the surface 2b (second surface) as one example. The walls 2k and 2m appear in a quadrangular shape (in the embodiment, a rectangular shape as one example) as viewed from the thickness direction (planar view). The wall 2k and the wall 2m are positioned apart from each other. The housing 2 further comprises four walls 2n (parts, plates, side walls, end walls, standing walls, or extending portions) having surfaces 2p (side surfaces or circumferential surfaces) extending between the wall 2k and the wall 2m. The housing 2 is provided with a space 2s (see FIGS. 2 and 3) inside. The space 2s is surrounded by the walls 2k, 2m, and 2n, positioned between the wall 2k and the wall 2m, extending between the end portion 2c and the end portion 2e, and extending between the end portion 2d and the end portion 2f. Various components can be housed in the space 2s. For example, a battery, a circuit board 2r (circuit board, control circuit board, or sub circuit board, see FIGS. 7 and 8), various modules, an optical disk drive (ODD), a hard disk drive (HDD), a solid state drive (SDD), an antenna, a camera module, a speaker unit, a connector unit, an operation module unit (switches), and a sensor unit, can be housed in the space 2s.

In the embodiment, a plurality of components (not illustrated) can be mounted on the circuit board 2r provided in the space 2s. For example, a central processing unit (CPU), a graphics controller, power supply circuit components, a platform controller hub (PCH), a memory slot connector, an LCD connector, an input/output (I/O) connector, a power coil, elements, and connectors. Furthermore, a control circuit can comprise, for example, a video signal processing circuit, a tuner, a High-Definition Multimedia Interface (HDMI) signal processor, an audio video (A/V) input terminal, a remote control signal receiver, a controller, a selector, an on-screen display interface, a storage module (for example, a read only memory (ROM), a random access memory (RAM), a hard disk drive (HDD), and a solid state drive (SSD)), and an audio signal processing circuit, can be mounted on the circuit board 2r. The control circuit controls such operations as the output of videos (such as movies and still pictures) on a display screen (surface 5a) of the display 5, the output of audio from a speaker (not illustrated), and light emission of a light emitting diode (LED, not illustrated). The display 5, the speaker, and the LED are examples of output modules.

The housing 2 can be configured by combining a plurality of components (segmented bodies). The housing 2 in the embodiment comprises: a member 21 (upper side member, mask, mask portion, cover, front cover, cover portion, portion, or area) comprising at least the wall 2k; and a member 22 (lower side member, base, base portion, bottom, bottom portion, cover, rear cover, cover portion, portion, or area) comprising at least the wall 2m as one example. The walls 2n are comprised in at least one of the member 21 and the member 22 (for example, the member 22). Moreover, the housing 2 can comprise another member (intermediate member, isolating member, barrier wall member, wall member, intervening member, covering member, inner plate, middle plate, middle frame, shield, portion, or area, not illustrated) positioned between the member 21 and the member 22. The housing 2 can be composed of metallic or synthetic resin material, for example. As one example, the member 21 can be composed of synthetic resin material and the member 22 can be composed of metallic material. Alternatively, the member 21 can be composed of metallic material and the member 22 can be composed of synthetic resin material. The member 21 and the member 22 can be composed of the same material, or each of the member 21 and the member 22 can comprise a portion composed of a material different from other portion thereof. The inner sides of the member 21 and the member 22 of the housing 2 can be provided with walls such as ribs (projecting portions or projecting walls, not illustrated). These walls facilitate an increase in rigidity of the housing 2.

On the surface 2a (the wall 2k) of the housing 2, a keyboard 6 (operation module, input module, keyboard module, or module), a touch pad 7 (pointing device or touch sensor), and others are provided. The keyboard 6 is positioned in a rectangular area on the side closer to the end portion 2c than the end portion 2e, and is supported by the wall 2k. The touch pad 7 is positioned closer to the end portion 2e than to the end portion 2c, and is mounted on the underside surface of the wall 2k. An area of the wall 2k located nearer to the end portion 2e than to the keyboard 6 is a palm rest 8. The touch pad 7 is positioned in a middle portion (central portion) of the palm rest 8 in the longer direction. The circuit board 2r is housed inside the housing at a back side of the keyboard 6 (inside the space 2s). Inside the housing 2 at a back side of the palm rest 8 (inside the space 2s), there is housed relatively thick components (tall components or electrical components, as one example, a battery and an ODD).

The housing 3 comprises, as illustrated in FIG. 1 as one example, a wall 3k (part, plate, frame, front wall, surface wall, or top wall) having a surface 3a (second surface or third surface), and a wall 3m (part, plate, rear wall, back wall, or bottom wall) having a surface 3b. The walls 3k and 3m appear in a quadrangular shape (in the embodiment, a rectangular shape as one example) as viewed from the thickness direction (planar view). The wall 3k and the wall 3m are spaced apart from each other. The housing 3 further comprises four walls 3n (parts, plates, side walls, end walls, standing walls, or extending portions) having surfaces 3p (side surfaces or circumferential surfaces) extending between the wall 3k and the wall 3m. Both the surface 3a and the surface 3b extend (expand) along a direction intersecting the thickness direction of the housing 3 (in the embodiment, in an orthogonal direction as one example). The surface 3a and the surface 3b are roughly in parallel with each other. As illustrated in FIGS. 1 to 3, the housing 3 further comprises four end portions 3c to 3f (sides or edge portions) and four corners 3g to 3j (protruding portions, rounded portions, or end portions) in the planar view. The end portions 3c and 3e are examples of longer sides. The end portions 3d and 3f are examples of shorter sides.

The display 5 (display module, display device, or component) in the embodiment is flexible, soft, pliable, and thin, and has a sheet-like (film-like) shape as one example. The display 5, for example, is a liquid crystal display (LCD) or an organic electroluminescent display (GELD). The display 5 is configured in a quadrangular shape (in the embodiment, a rectangular shape as one example) as viewed from the thickness direction (planar view). The display 5 comprises: the surface 5a (display surface, anterior surface, front face, top surface, surface, or display screen) on which an image can be viewed; and a surface 5b (rear surface, back surface, bottom surface, or underside surface) opposite the surface 5a. The display 5 further comprises four end portions 5c to 5f (sides or edge portions) and four corners 5g to 5j (protruding portions, rounded portions, or end portions) in the planar view. The end portions 5c and 5e are examples of shorter sides. The end portions 5d and 5f are examples of longer sides. The display 5 can be provided with a touch sensor (not illustrated). The touch sensor is colorless and transparent, and can be positioned in a layer configuring the display 5 or a layer covering the surface 5a of the display 5.

In the embodiment, the display 5 covers the surface 3a of the housing 3 as one example. More specifically, the display 5 is positioned on the surface 3a. In other words, the housing 3 covers the surface 5b of the display 5. Furthermore, the display 5 is supported by the housing 2 and the housing 3. The housing 2 supports an area of the display 5 at one side with respect to a middle portion of display 5 in a longer direction thereof (in the embodiment, the end portion 5e side as one example), and the housing 3 supports an area of the display 5 at other side with respect to the middle portion (in the embodiment, the end portion 5c side as one example). On the circumferential edge portions (the end portions 5c to 5f) of the display 5, a rectangular and frame-like non-display area (not illustrated) is provided. Furthermore, the display 5 is electrically connected to the circuit board 2r via wiring (for example, a flexible printed circuit (FPC), not illustrated) and such.

Moreover, the display 5 is housed in a storage 2t provided inside the housing 2 in an ejectable-retractable manner. In the embodiment, as illustrated in FIG. 2 as one example, the storage 2t is positioned with respect to the wall 2m of the housing 2 at an inner side of the housing 2 and at the end portion 2c side. Guides 2u extending along the end portions 5d and 5f are provided to the wall 2m. Each of the pair of guides 2u comprises a wall 2u1 projecting from the wall 2m, and a wall 2u2 projecting from the end portion of the wall 2u1 in a direction to be close to each other. The each of the guides 2u has an L-shaped cross-section. The display 5 is positioned toward the wall 2m side by the guides 2u. The guide 2u can comprise a friction reducing portion (not illustrated) composed of relatively slippery synthetic resin material (of low friction coefficient), for example, polytetrafluoroethylene, at least for the portions thereof contacting the display 5. The friction reducing portion can be provided on the display 5 by being applied or adhered thereto. The friction reducing portion can be provided on portions of the display 5 at which the display 5 makes contact with the housing 2 and the housing 3.

As will be apparent by comparing FIGS. 1 and 2, the storage 2t and the display 5 are positioned on the back side of the keyboard 6. As illustrated in FIG. 8, the storage 2t and the display 5 are positioned on the side opposite the keyboard 6 with respect to the wall 2k, and are positioned opposite the wall 2k, on which components 9 (such as the circuit board 2r and components 9a provided on the circuit board 2r) are provided, with respect to the components 9. More specifically, the storage 2t and the display 5 are positioned closer to the surface 2b than to the surface 2a. Such arrangement allows the display 5 to be arranged (housed) in a less troublesome manner in the housing 2, for example, preventing interference with the components 9. Because the keyboard 6 and the components 9 are electrically connected via the wiring (for example, FPC, not illustrated), this arrangement can avoid the interference between the display 5 and the wiring and increase the degree of freedom in layout of the components 9, as one example. Furthermore, by arranging the storage 2t and the display 5 close to the end portion 2c side in the housing 2, it becomes possible to arrange relatively thick components 9 (see FIG. 1) in the space 2s on the end portion 2e side while avoiding the interference with the display 5.

The display 5 in the embodiment is supported by both the housing 2 and the housing 3, as one example. The portion of the display 5 on the housing 2 side is positioned inside the housing 2. Meanwhile, on the housing 3 side, the display 5 is exposed toward the surface 3a side from an opening 3r provided on the end portion 3e. The display 5 extends between the end portion 3e and the end portion 3c, covering the surface 3a. Furthermore, at least in the unfolded state, the display 5 can extend (protrude) out of the housing 3 (out of the end portion 3c opposite the end portion 3e), exceeding the end portion 3c. The display 5 can move (slide) between a first position P1 (housed position, see FIG. 3) in which the display 5 is stored in the storage 2t of the housing 2, and a second position P2 (projecting position, see FIGS. 2 and 3) in which the display 5 is taken out from the storage 2t and extended toward outside from the end portion 3c.

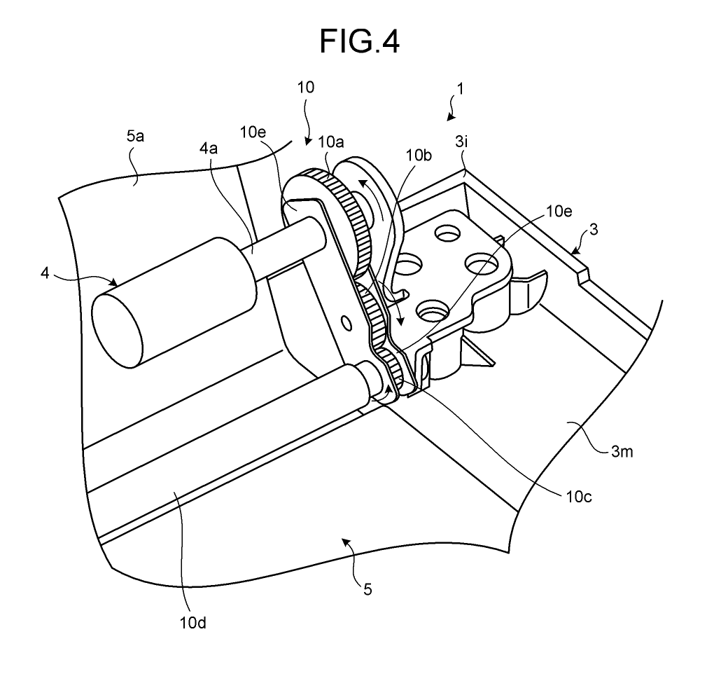

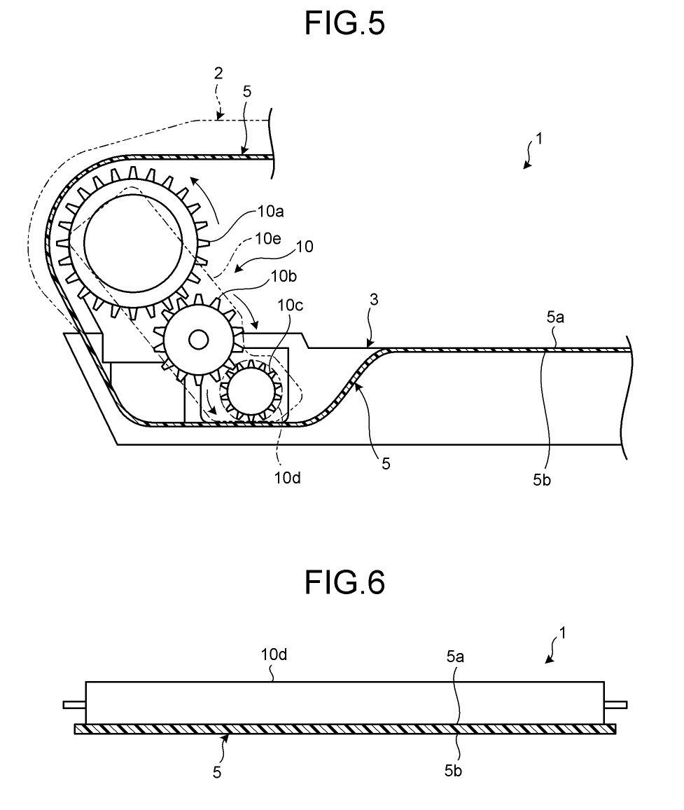

In the embodiment, the electronic device 1 comprises a driving portion 10 that moves the display 5 between the first position P1 and the second position P2, as one example. The driving portion 10 moves the display 5 by being moved by the housing 2 or the housing 3 (in the embodiment, the housing 2 as one example) in association with the movement (relative movement) of the housing 2 and the housing 3. In the embodiment, the driving portion 10 moves the display 5 in a direction toward which the display 5 is ejected from the storage 2t by the motion of the driving portion 10 associated with the unfolding of the housing 2 and the housing 3. Further, the driving portion 10 moves the display 5 in a direction toward which the display 5 is retracted into the storage 2t by the motion of the driving portion 5 associated with the unfolding of the housing 2 and the housing 3, as one example. Specifically, as illustrated in FIGS. 4 to 8, the driving portion 10 comprises a gear 10a (first gear), a gear 10b (third gear), a gear 10c (second gear), a roller 10d (rotating portion), a supporting portion 10e, and/or the like. The gears 10a to 10c are all rotatably supported by the supporting portion 10e. All of the gears 10a to 10c are rotatably supported about the rotational axis Ax along the end portions 3e and 2c and in parallel with each other. The supporting portion 10e is fixed to the housing 2. The gear 10a is fixed to a shaft 4a of the hinge 4 and rotates together with the housing 3. The gears 10b and 10c are rotatably supported by the supporting portion 10e, i.e., the housing 2. The gear 10b is positioned between the gear 10a and the gear 10c, and is engaged with both of the gear 10a and the gear 10c. The rotational direction of the gear 10b is reverse of the rotational direction of the gear 10a. The gear 10c is fixed to the roller 10d. The gear 10c and the roller 10d rotate concentrically. The roller 10d is in contact with the display 5, and sends the display 5. More specifically, the display 5 is moved between the first position P1 and the second position P2 in association with the rotation of the roller 10d. The portion of the roller 10d that is in contact with the display 5 is composed of, for example, elastomer. As indicated by arrows in FIGS. 4 and 5, when the housing 3 rotates in the counter-clockwise direction in FIGS. 4 and 5 with respect to the housing 2, the gear 10a rotates in the counter-clockwise direction in FIGS. 4 and 5, the gear 10b rotates in the clockwise direction in FIGS. 4 and 5, and the gear 10c and the roller 10d rotate in the counter-clockwise direction in FIGS. 4 and 5. Accordingly, the display 5 moves in the right-hand direction in FIGS. 4 and 5. When the housing 3 rotates in the clockwise direction in FIGS. 4 and 5 with respect to the housing 2, the gears 10a to 10c and the roller 10d rotate in the counter directions to the respective arrows in FIGS. 4 and 5, and the display 5 moves in the left-hand direction in FIGS. 4 and 5. Consequently, in accordance with the driving portion 10, the display 5 moves in response to the folding of the housings 2 and 3 illustrated in FIG. 7 and the unfolding of the housings 2 and 3 illustrated in FIG. 8 (i.e., the rotation (movement) of the housings 2 and 3 illustrated in FIGS. 7 and 8). Here, such a configuration is merely an example, and the display 5 may be configured to move between the first position P1 and the second position P2 by manual operation, for example, with hands and fingers of the operator.

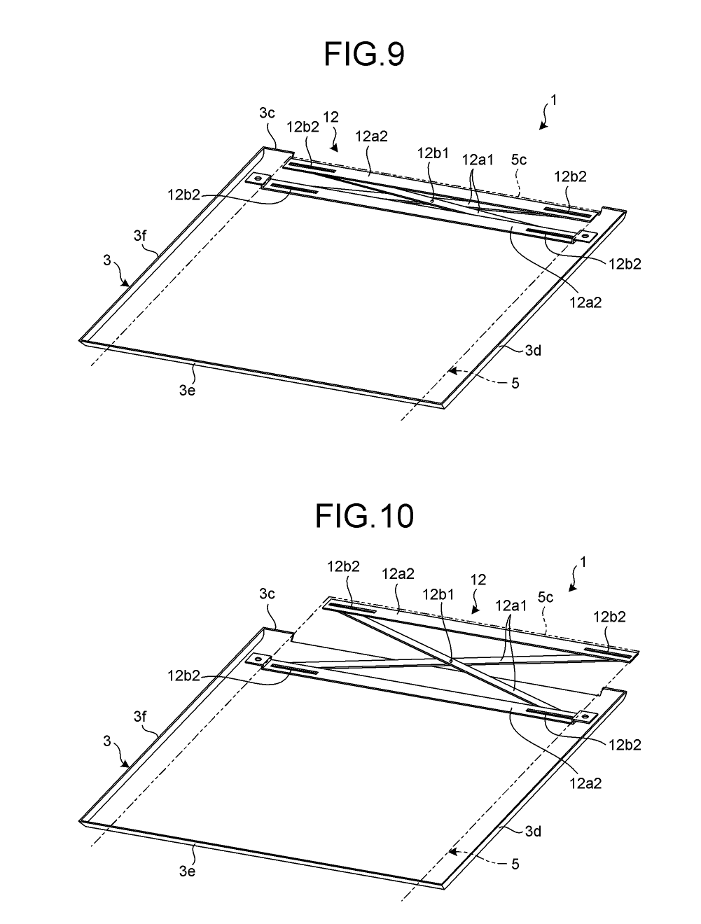

In the embodiment, as illustrated in FIGS. 3, 9, and 10 as one example, there is provided movable portions 11 and 12 that shrink and stretch in coordination with the movement of the display 5. The movable portion 11 is configured, as illustrated in FIG. 3, as a link mechanism in which a plurality of links 11a1 and 11a2 are rotatably or slidably coupled with each other at a coupling point 11b. The movable portion 12 is configured, as illustrated in FIGS. 9 and 10, as a link mechanism in which a plurality of links 12a1 and 12a2 are rotatably or slidably coupled with each other at coupling points 12b1 and 12b2. The movable portion 11 is configured as a parallel link mechanism, and two pieces of the links 11a1 rotate while retaining a condition parallel to each other. Accordingly, as illustrated in FIG. 3, the end portion 5e of the display 5 to which the links 11a2 are attached can perform parallel movement. More specifically, by the movable portion 11, the inclination of the display 5 is suppressed. Meanwhile, with the movable portion 12, central portions of two pieces of the links 12a1 arranged to cross with each other are connected to rotate at the coupling point 12b1. The end portions of the two links 12a1 in the longer direction are coupled to the links 12a2 to slide at the coupling points 12b2. Accordingly, as illustrated in FIGS. 9 and 10, the end portion 5c of the display 5 attached to the leading end side (tip side) of the link 12a2 can perform parallel movement. More specifically, by the movable portion 12, the inclination of the display 5 is suppressed. Furthermore, the movable portion 12 can support the portion of the display 5 projecting from the housing 3 regardless of the projecting amount (projecting condition) thereof. The movable portions 11 and 12 serve as a guide for the display 5.

As in the foregoing, in the embodiment, the driving portion 10 moves the display 5 in accordance with the unfolding of the housing 2 and the housing 3 to move the display 5 in the direction toward which the display 5 is eject from the storage 2t, as one example. Further, the driving portion 10 moves the display 5 in accordance with the folding of the housing 2 and the housing 3 to move the display 5 in the direction toward which the display 5 is retracted into the storage 2t, as one example. Therefore, in accordance with the embodiment, as compared with the display 5 handled by manual operation, troubles in operation by the operator are likely to be reduced as one example.

Furthermore, in the embodiment, in the state in which the housing 2 and the housing 3 are unfolded, the display 5 is protrudable from the end portion 3c towards the side opposite the end portion 3e as one example. Therefore, in accordance with the embodiment, a user can use the display 5 wider in the unfolded state (use condition), and on the other hand, the electronic device 1 becomes more compact in the folded condition (non-use condition), as one example.

In the embodiment, the storage 2t stores therein the display 5 at a position closer to the surface 2b than the surface 2a as one example. Therefore, in accordance with the embodiment, as compared with the display 5 stored at a position close to the surface 2a, the curvature radius of the display 5 bent in the folded state is likely to be larger as one example. Consequently, the load to the display 5 is likely to be reduced. Furthermore, the interference with the components 9 in the housing 2 is likely to be suppressed as one example.

In the embodiment, the storage 2t sores therein the display 5 on the side opposite the wall 2k with respect to the circuit board 2r as one example. Therefore, in accordance with the embodiment, the keyboard 6 and the circuit board 2r are likely to be electrically connected more easily as one example.

In the embodiment, the electronic device 1 comprises the movable portions 11 and 12 that shrinks and stretches in accordance with the movement of the display 5 as one example. Therefore, in accordance with the embodiment, the display 5 is likely to move more smoothly or more accurately. Moreover, in accordance with the embodiment, the display 5 is likely to be supported more stably regardless of the position of the display 5.

In the embodiment, the driving portion 10 comprises: the roller 10d that sends the display 5 by being in contact with the display 5 and rotated; the gear 10a fixed to one of the housing 2 and the housing 3 (in the embodiment, the housing 3 as one example); and the gear 10c that is supported on the other one of the housing 2 and the housing 3 (in the embodiment, the housing 2 as one example), rotated in accordance with the gear 10a, and fixed to the roller 10d as one example. Therefore, in accordance with the embodiment, the driving portion 10 can be configured to be relatively simple, as one example. Furthermore, the display 5 is likely to move more reliably. Moreover, by the setting of gear ratio and such, the moving condition (moving speed and amount of move) of the display 5 is likely to be adjusted with relative ease.

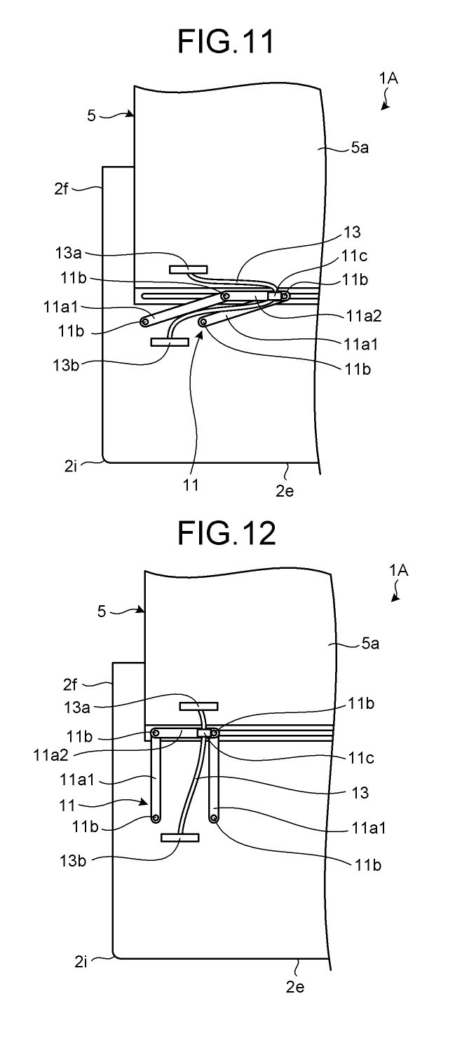

An electronic device 1A according to a first modification illustrated in FIGS. 11 and 12 comprises a similar configuration as that of the above-described embodiment. Therefore, the first modification can yield similar operations and results (effects) based on a similar structure to those in the embodiment. In the first modification, a wiring 13 that connects the display 5 and the circuit board 2r (see FIGS. 7, 8, and others) with each other is supported by the movable portion 11. Specifically, on a supporting portion 11c provided to the link 11a2 of the movable portion 11, an opening (not illustrated) through which the wiring 13 passes is provided. As illustrated in FIG. 11, in the state in which the display 5 is positioned at the first position P1, the wiring 13 is bent because an end portion 13a of the wiring 13 on the display 5 side and an end portion 13b of the wiring 13 on the housing 2 side are placed close to each other. In the state in which the display 5 is positioned at the first position P1 and the movable portion 11 is retracted, as compared with the state in which the display 5 is positioned at the second position P2 and the movable portion 11 being extended, the link 11a2 is positioned away from the end portions 13a and 13b. Therefore, in accordance with the first modification, the bent portion of the wiring 13 can be supported by the supporting portion 11c provided to the link 11a2, whereby the wiring 13 can be prevented from bending in an inconvenient manner. As one example, by appropriately arranging the end portions 13a and 13b of the wiring 13 and the supporting portion 11c such as the end portions 13a and 13b of the wiring 13 and the supporting portion 11c being lined roughly in a straight line while the display 5 is positioned at the second position P2, the wiring 13 can be prevented from bending in an inconvenient manner. Similar operations and effects can be yielded when the supporting portion 11c is provided in an area of the movable portion 11 whose position in a retracted condition is spaced apart in a relatively large way from that in an extended condition, for example, an end portion of the link 11a1 on the link 11a2 side.

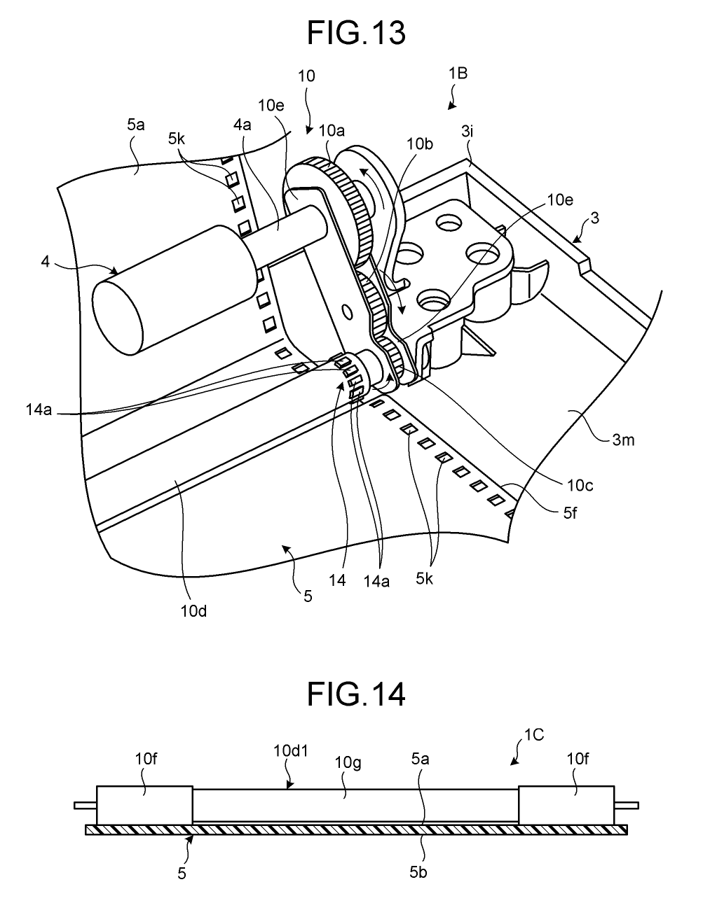

An electronic device 1B according to a second modification illustrated in FIG. 13 comprises a similar configuration as that of the aforementioned embodiment and the modification. Therefore, the second modification can yield similar operations and results (effects) based on a similar structure to those in the embodiment and the modification. In the second modification, the roller 10d is provided with a sprocket 14. The sprocket 14 comprises a plurality of teeth 14a arranged in a constant interval in a circumferential direction thereof. A plurality of openings 5k are provided on an end portion 5f of the display 5 at a constant interval corresponding to the teeth 14a of the sprocket 14. In accordance with the second modification, the teeth 14a enter the openings 5k provided on the display 5 and push the circumferential edge portions of the openings 5k in response to the rotation of the roller 10d, whereby the display 5 can be sent. The moving direction of the display 5 with respect to the rotational directions of the gears 10a to 10c and the roller 10d is the same as that in the embodiment. In accordance with the second modification, the slippage between the roller 10d and the display 5 is likely to be suppressed, as one example. Consequently, the display 5 is likely to be moved more reliably as one example.

An electronic device 1C according to a third modification illustrated in FIG. 14 comprises a similar configuration as that of the aforementioned embodiment and the modifications. Therefore, the third modification can yield similar operations and results (effects) based on a similar structure to those in the embodiment and the modifications. In the third modification, the diameter of end portions 10f of a roller 10d1 in the longer direction is larger than that of a central portion 10g in the longer direction. In accordance with the third modification, even when the display 5 is warped in the width direction, the end portions 10f are likely to contact the display 5, whereby the rotation of the roller 10d1 is likely to be transferred to the display 5, as one example.

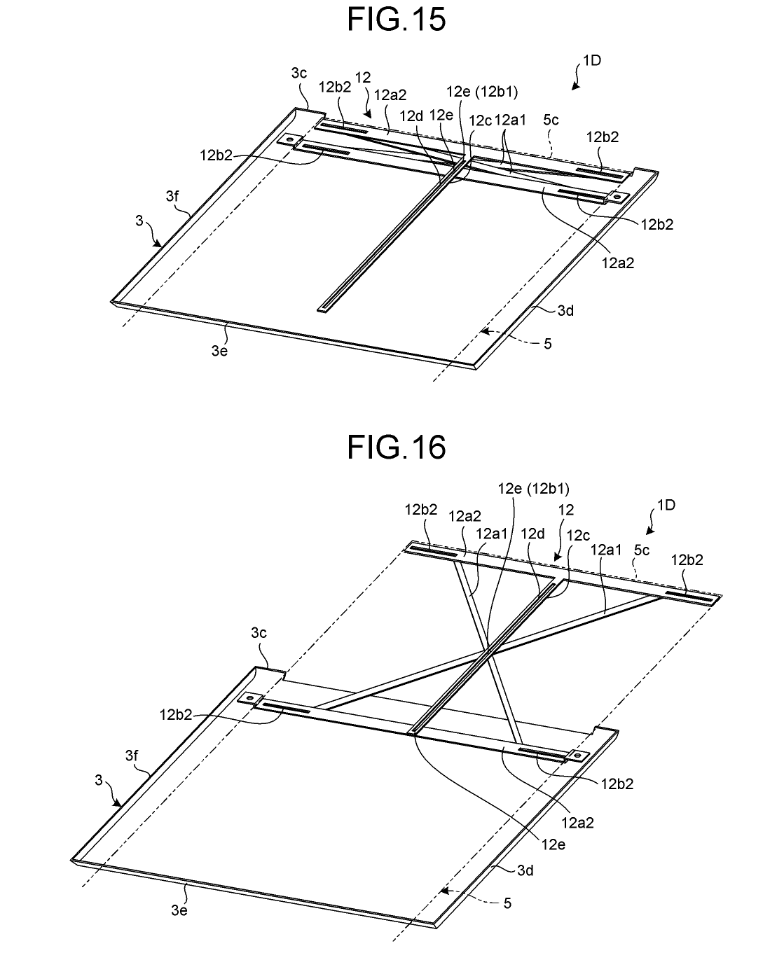

An electronic device 1D according to a fourth modification illustrated in FIGS. 15 and 16 comprises a similar configuration as that of the aforementioned embodiment and the modifications. Therefore, the fourth modification can yield similar operations and results (effects) based on a similar structure to those in the embodiment and the modifications. In the fourth modification, a guide 12c (supporting portion) is provided on the link 12a2 of the movable portion 12 on the tip side. The guide 12c extends in a belt-like (plate-like) shape from the tip side to the base end side along the moving direction (extending and retracting direction) of the display 5. On the guide 12c, a rail 12d (for example, a through hole) is provided. On the coupling point 12b1 of the links 12a1 and on the links 12a2 on the base end sides, sliders 12e (for example, projections) are provided. The sliders 12e are guided along the rail 12d. In accordance with the fourth modification, the display 5 is additionally supported by the guide 12c as one example. Consequently, an area of the display 5 outside (leading end side) from the end portion 3c of the housing 3 becomes even harder to warp, as one example.

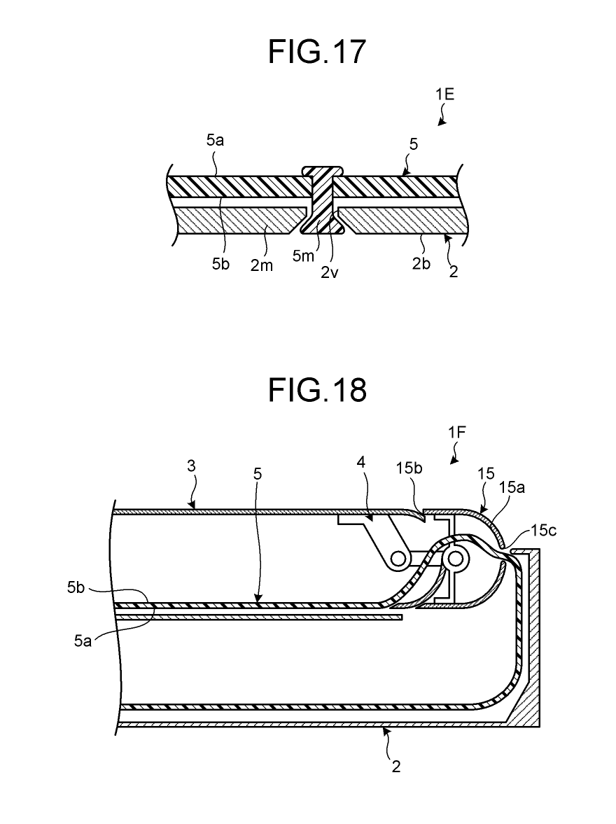

An electronic device 1E according to a fifth modification illustrated in FIG. 17 comprises a similar configuration as that of the aforementioned embodiment and the modifications. Therefore, the fifth modification can yield similar operations and results (effects) based on a similar structure to those in the embodiment and the modifications. In the fifth modification, a slider 5m (guide) provided on the display 5 is guided along a rail 2v (guide) provided on the wall 2m of the housing 2. The slider 5m is fixed to a portion positioned inside the storage 2t, such as the end portion 5e of the display 5. The rail 2v is provided as a through-bore (opening) that runs through the wall 2m and extends along the moving direction of the display 5 (i.e., along the end portions 2d and 2f). In accordance with the fifth modification, the slider 5m and the rail 2v serve as a guide similarly to the movable portions 11 and 12 as one example. Consequently, as one example, the inclination of the display 5 is likely to be suppressed.

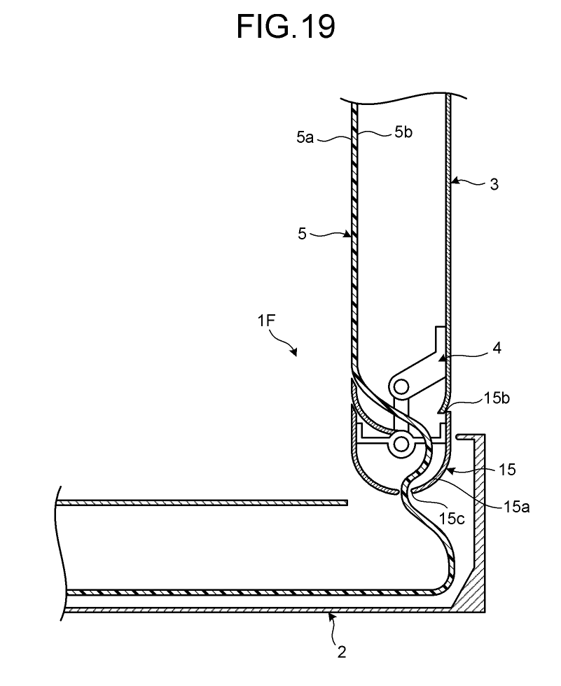

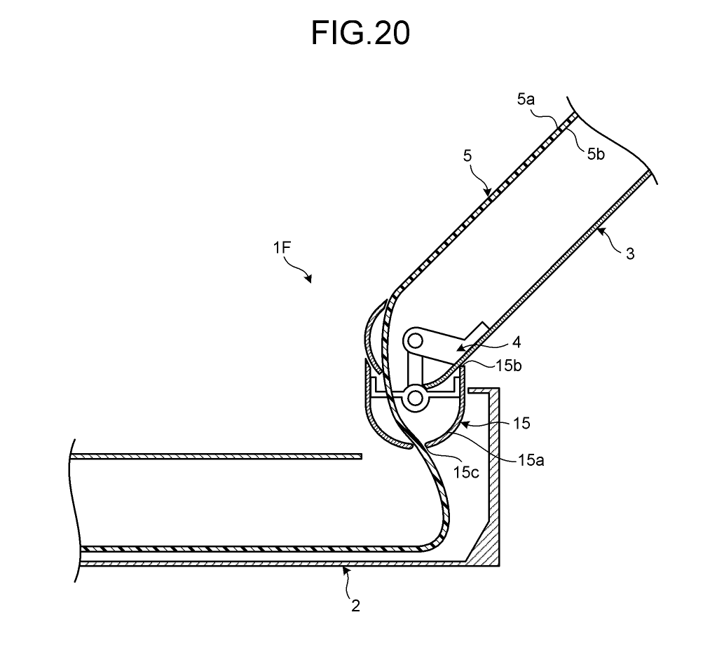

An electronic device 1F according to a sixth modification illustrated in FIGS. 18 to 20 comprises a similar configuration as that of the aforementioned embodiment and the modifications. Therefore, the sixth modification can yield similar operations and results (effects) based on a similar structure to those in the embodiment and the modifications. In the sixth modification, a cover 15 covering the hinge 4 and the display 5 is provided between the housing 2 and the housing 3. The cover 15 is rotatably supported by at least one of the housing 2 and the housing 3. As one example, the cover 15 can be rotatably supported by a portion of the hinge 4. The cover 15 comprises a wall 15a having a U-shaped cross-section. An opening 15b on the housing 3 side is provided on the opened side of the U-shaped cover 15. An opening 15c is provided on the wall 15a in a slit shape extending along the end portion 2c at the position of the bottom of the U-shape. The display 5 runs through the openings 15b and 15c. As illustrated in FIGS. 18 and 19, the cover 15 moves in association with the housing 3 between the folded state and the state in which the housings 2 and 3 forms an angle of 90 degrees in the side view. Then, as illustrated in FIG. 20, in a state in which the electronic device 1F is unfolded for an amount greater than that illustrated in FIG. 19, the cover 15 no longer follows the housing 3, and the cover 15 and the housing 3 make an abrupt bend. Consequently, in accordance with the sixth modification, for the extent of the cover 15 being provided, it becomes difficult for the display 5 to be exposed (hard to be seen from outside) at the border between the housing 2 and the housing 3.

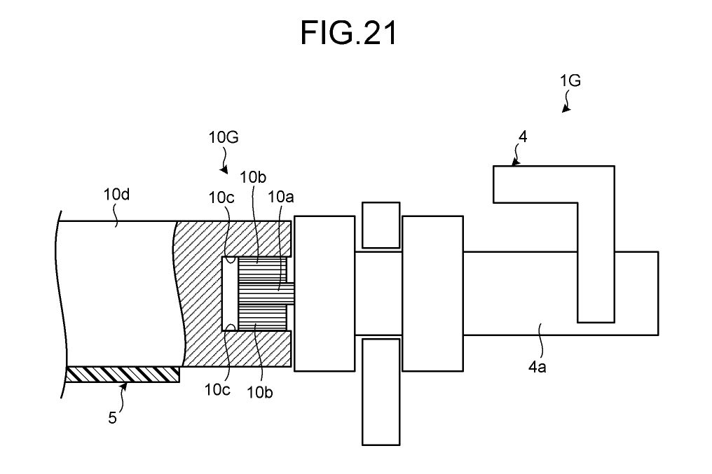

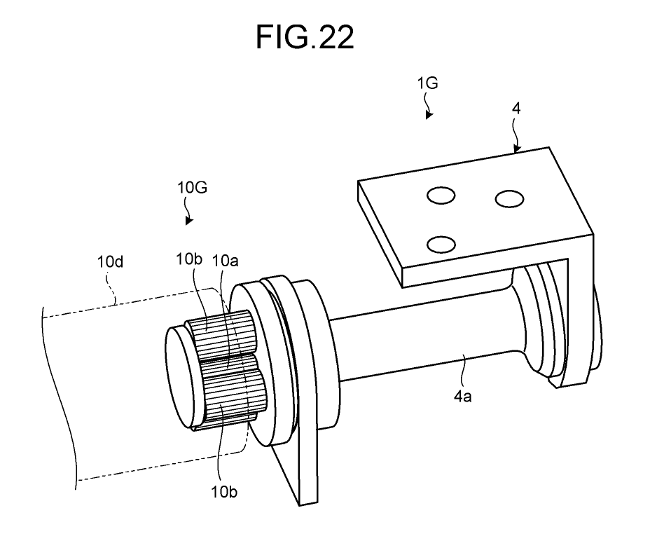

An electronic device 1G according to a seventh modification illustrated in FIGS. 21 and 22 comprises a similar configuration as that of the aforementioned embodiment and the modifications. Therefore, the seventh modification can yield similar operations and results (effects) based on a similar structure to those in the embodiment and the modifications. In the seventh modification, a driving portion 10G is configured as a planetary gear mechanism. More specifically, the gear 10a is configured as a sun gear, the gear 10b is configured as planetary gears, and the gear 10c is configured as a ring gear, and the roller 10d is fixed to the gear 10c. The seventh modification can yield the same rotational directions as those of the driving portion 10. The driving portion 10G in the seventh modification may be configured to be more compact as compared with the driving portion 10, as one example.

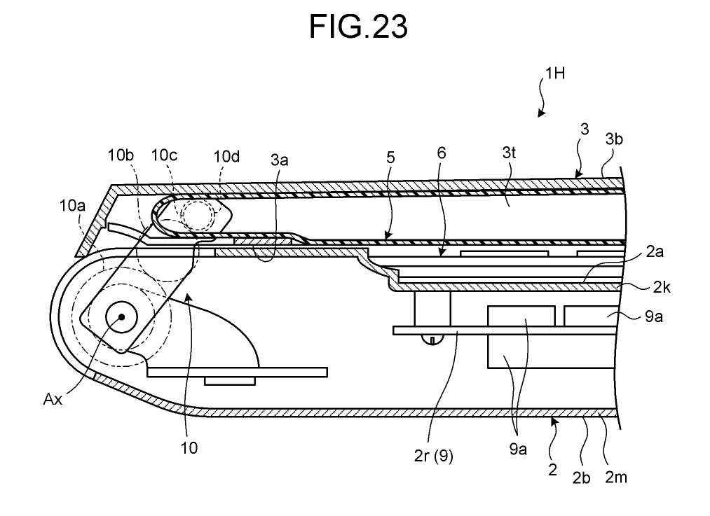

An electronic device 1H according to an eighth modification illustrated in FIG. 23 comprises a similar configuration as that of the aforementioned embodiment and the modifications. Therefore, the eighth modification can yield similar operations and results (effects) based on a similar structure to those in the embodiment and the modifications. In the eighth modification, the display 5 is housed in the housing 3. More specifically, a storage 3t is provided on the wall 3m side of the housing 3, and stores therein the display 5 at a position closer to the surface 3b than the surface 3a. In the eighth modification, the display 5 moves in association with the rotation of the housings 2 and 3. In accordance with the eighth modification, as compared with the display 5 housed in the housing 2, the configuration of the electronic device 1H may be more likely to be simplified in some cases as one example.

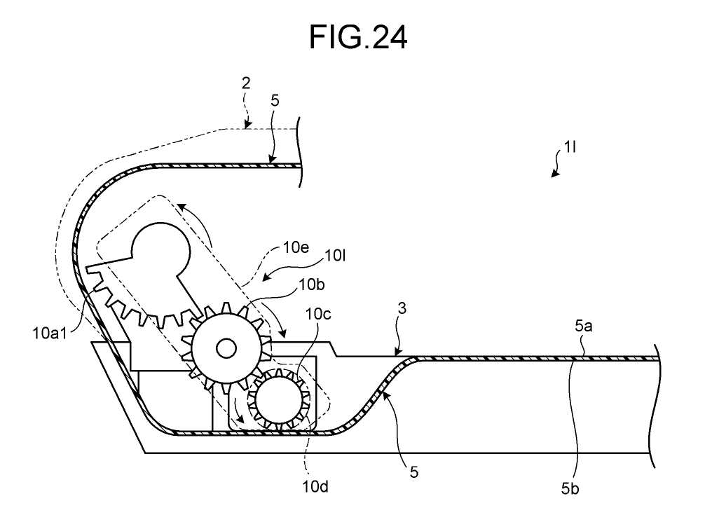

An electronic device 1I according to a ninth modification illustrated in FIGS. 24 to 26 comprises a similar configuration as that of the aforementioned embodiment and the modifications. Therefore, the ninth modification can yield similar operations and results (effects) based on a similar structure to those in the embodiment and the modifications. In the ninth modification, the operational angle of a gear 10a1 is restricted. Accordingly, when the housing 3 is to be rotated from the folded state to the maximally unfolded state (for example, a 180 degree-expanded condition), the gear 10a1 stops the rotation of the gears 10b and 10c and the roller 10d from when a predetermined angle between the housing 2 and the housing 3 (defined angle or standing state defined between the folded state and the maximally unfolded state) is reached and until when the housing 3 is rotated to the maximally unfolded state. More specifically, in the ninth modification, the display 5 is maximally pulled-out (maximally pulled-out state, maximally protruded state or maximally exposed state) at the given angle, and from the given angle to the maximally unfolded condition, the display 5 remains in the maximally pulled-out state.

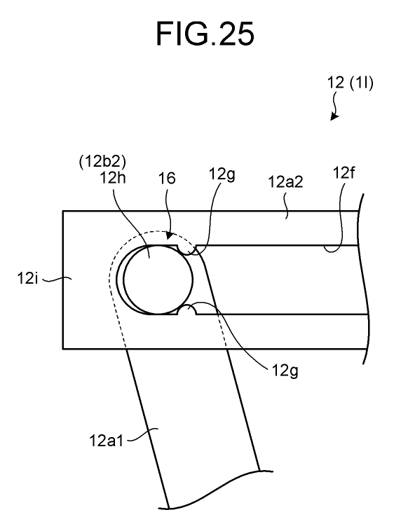

Furthermore, in the ninth modification, as illustrated in FIG. 25 as one example, snap-fit mechanisms 16 (retaining mechanisms or retaining portions) are provided at the respective coupling points 12b2 of the links 12a1 and the links 12a2 of the movable portion 12. The snap-fit mechanism 16 is configured by projections 12g (narrowed portion) of a rail 12f provided on the link 12a2 and a slider 12h provided on the link 12a1 to slide on the rail 12f. In the state in which the display 5 is maximally pulled out, the slider 12h moves beyond the projections 12g and is retained on an end portion 12i side than the projections 12g of the rail 12f. At the time of folding the housing 2 and the housing 3, when the gear 10a1 and the gear 10b of a driving portion 10l engage with each other, the gear 10c and the roller 10d rotate, and a force from the display 5 acts on the base end portion of the link 12a2 (on the end portion 3e side), the slider 12h moves beyond the projections 12g and moves towards the side opposite to the end portion 12i with respect to the projections 12g of the rail 12f.

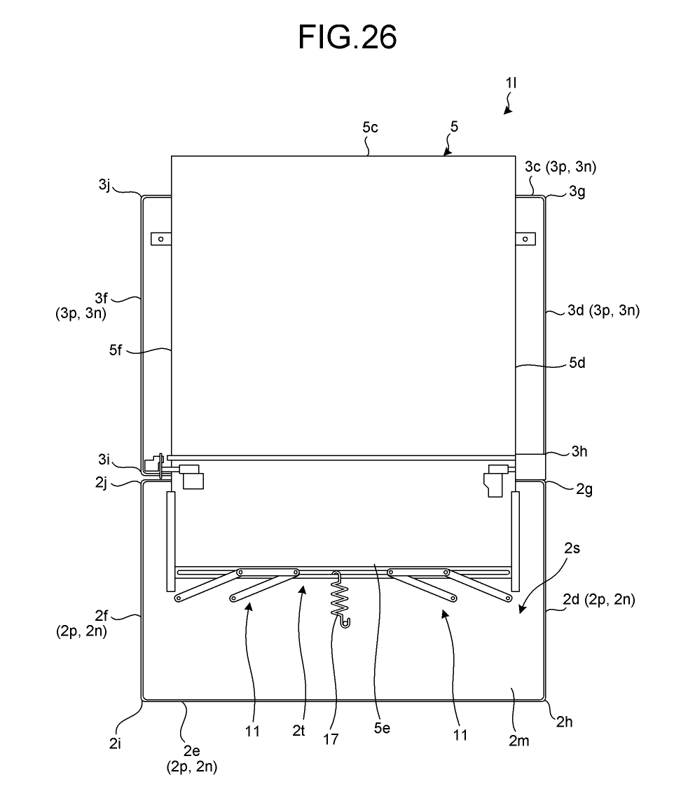

Moreover, in the ninth modification, as illustrated in FIG. 26 as one example, there is provided a coil spring 17 (elastic member) that exerts force (elastic force) to the display 5 in a direction in which the display 5 is retracted (returns) into the storage 2t. The coil spring 17 provides tension to the display 5 and assists the display 5 to be retracted into the storage 2t. In accordance with the aforementioned ninth modification, the user can use the more widely pulled out (projecting or exposed) display 5 regardless of the angle of the unfolded state. Here, the coil spring 17 can be replaced with a torsion spring, a plate spring, elastomer, and such.

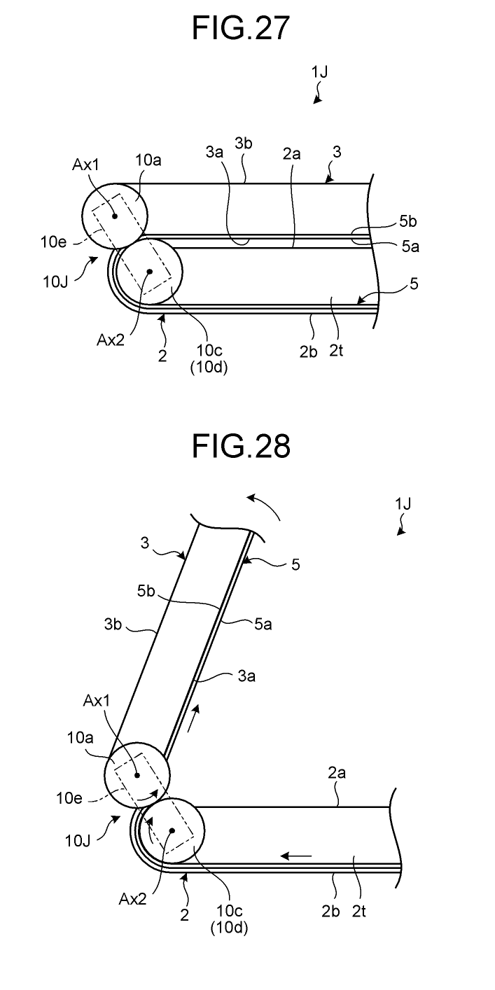

An electronic device 1J according to a tenth modification illustrated in FIGS. 27 and 28 comprises a similar configuration as that of the aforementioned embodiment and the modifications. Therefore, the tenth modification can yield similar operations and results (effects) based on a similar structure to those in the embodiment and the modifications. In the tenth modification, a driving portion 10J comprises the gears 10a and 10c, the roller 10d, the supporting portion 10e, and/or the like, but not the gear 10b in the middle. The gear 10a and the gear 10c are engaged with each other, and rotated in a counter direction with respect to each other. The gear 10a is fixed to the housing 3. The gear 10a is rotatable about a rotational axis Ax1. The gear 10c is rotatably supported by the housing 2 about a rotational axis Ax2. The gear 10c is fixed to the roller 10d that rotates concentrically (about the rotational axis Ax2). The display 5 moves along with the rotation of the roller 10d. The supporting portion 10e is fixed to the housing 2. The housing 3 is rotatably supported by the supporting portion 10e (the housing 2) t about the rotational axis Ax1. The driving portion 10J can be covered by the housing 3, the housing 2, or a member (not illustrated) provided on the foregoing.

In such a configuration, when the housing 3 rotates in the counter-clockwise direction in FIGS. 27 and 28 from the folded state towards the maximally unfolded state, the gear 10a rotates together with the housing 3 in the same direction (the counter-clockwise direction in FIGS. 27 and 28). The gear 10c that is engaged with the gear 10a then rotates in a counter direction to the rotational direction of the gear 10a (the clockwise direction in FIGS. 27 and 28). The roller 10d rotates in the same direction as that of the gear 10c (the clockwise direction in FIGS. 27 and 28), and sends the display 5 from the storage 2t towards the leading end side of the housing 3. On the other hand, when the housing 3 rotates from the unfolded state towards the folded state, the gears 10a and 10c and the roller 10d rotate in the directions opposite to those in expanding, respectively. The display 5 moves in the direction opposite to that in expanding, and is stored in the storage 2t. In accordance with the tenth modification, for the extent of the gear 10b not being comprised, the driving portion 10J is likely to be configured more simply.

While the embodiment and the modifications of the present invention have been exemplified in the foregoing, these embodiment and modifications have been presented by way of example only, and are not intended to limit the scope of the invention. These embodiment and modifications described herein can be embodied in a variety of other forms, and various omissions, substitutions, combinations, and changes to these embodiment and modifications can be made without departing from the spirit of the invention. Such embodiment and modifications would fall within the scope and spirit of the invention and are intended to be covered by the accompanying claims and their equivalents. Furthermore, the structures and shapes in the above-described embodiment and the modifications can be implemented while partially replaced with one another. The specifications (such as the configuration, type, direction, shape, size, length, width, thickness, height, number of pieces, arrangement, position, and material) of each of the structures and shapes can be implemented with appropriate changes. The advantages attributable to the structures and shapes in each of the embodiment and the modifications may be achieved irrelevantly to the advantages of the other structures and shapes. Furthermore, the projecting amount of the flexible display can be set with appropriate changes. The number of gears and the arrangement of the driving portion can be changed appropriately.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a first housing comprising a first surface comprising a keyboard;
a second housing configured to foldably connect to the first housing and comprising a second surface positioned close to the first surface in a folded state and positioned away from the first surface in an unfolded state;
a flexible display comprising a display surface, configured to be stored in a storage provided to the first housing in an ejectable-retractable manner, configured to at least partially cover the second surface in a state in which at least a portion of the flexible display is out of the storage, and configured to be supported by the first housing and the second housing; and
a driving portion configured to move the flexible display in a direction toward which the flexible display is ejected from the storage by motion of the driving portion associated with unfolding of the first casing and the second casing, and configured to move the flexible display in a direction toward which the flexible display is retracted into the storage by the motion of the driving portion associated with folding of the first housing and the second housing.

2. The electronic device of claim 1, wherein
the second housing comprises:
a first end portion; and
a second end portion opposite the first end portion and positioned farther from the first housing than the first end portion in the state in which the first housing and the second housing are unfolded, and
the flexible display is configured to protrude from the second end portion towards a side opposite the first end portion in the state in which the first housing and the second housing are unfolded.

3. The electronic device of claim 1, wherein the storage stores the flexible display at a position closer to the second surface than to the first surface.

4. The electronic device of claim 1, further comprising:
a first wall provided to the first housing and configured to support the keyboard; and
a circuit board housed in the first housing, fixed to the first wall, and positioned opposite the keyboard, wherein
the storage stores the flexible display at a side opposite the first wall with respect to the circuit board.

5. The electronic device of claim 1, further comprising a movable portion configured to stretch and shrink in association with movement of the flexible display.

6. The electronic device of claim 1, wherein the driving portion comprises:
a rotating portion configured to move the flexible display by being in contact with the flexible display and rotated;
a first gear fixed to one of the first housing and the second housing; and
a second gear configured to be rotatably supported by other one of the first housing and the second housing, to be rotated in association with the first gear, and fixed to the rotating portion.

7. The electronic device of claim 6, wherein the rotating portion is a roller.

8. The electronic device of claim 6, wherein
the rotating portion is a sprocket, and
the flexible display comprises openings corresponding to teeth of the sprocket.

9. An electronic device comprising:
a first housing comprising a first surface and a second surface opposite the first surface;
a second housing foldably connected to the first housing and comprising a third surface positioned close to the first surface in a folded state and positioned away from the first surface in an unfolded state; and
a flexible display comprising a display surface, configured to be stored in the first housing in an ejectable-retractable manner at a position closer to the second surface than to the first surface, configured to at least partially cover the first surface in a state in which at least a portion of the flexible display is out of the first housing, and configured to be supported by the first housing and the second housing.

10. An electronic device comprising:
a first housing;
a second housing rotatably connected to the first housing;
a flexible display comprising a display surface and configured to be supported by at least one of the first housing and the second housing so as to be movable between a first position in which the flexible display is housed in at least one of the first housing and the second housing and a second position in which a larger area of the surface is exposed than an area of the surface exposed at the first position; and
a driving portion configured to move the flexible display in accordance with movement of one of the first housing and the second housing with respect to other one of the first housing and the second housing.
